(19) United States
(12) Patent Application Publication
(10) Pub. No.: US 2022/0131063 A1
(43) Pub. Date: Apr. 28, 2022

(54) ON-CHIP TUNABLE DISSIPATIONLESS INDUCTOR

(71) Applicant: The University of British Columbia, Vancouver (CA)

(72) Inventors: Joseph SALFI, Vancouver (CA); Karim ELKHOLY, Vancouver (CA); Mohammad KHALIFA, Vancouver (CA)

(21) Appl. No.: 17/508,810

(22) Filed: Oct. 22, 2021

Related U.S. Application Data
(60) Provisional application No. 63/105,041, filed on Oct. 23, 2020.

(51) Int. Cl. H01L 39/06; H01L 39/16; H01L 39/12; H01F 6/06

(52) U.S. Cl. CPC H01L 39/06; H01F 6/06; H01L 39/12; H01L 39/16

(57) ABSTRACT

A controllable superconducting inductor circuit comprises: a plurality of sub-circuits, each sub-circuit comprising: an inductor element; and a control element coupled to the inductor element to induce current in the inductor element in response to a control signal received at the control element. The inductor elements from the plurality of sub-circuits are arranged in parallel between a first pair of nodes to provide a tunable total inductance Lₜᵤₙ. For each of the plurality of sub-circuits, the inductor element behaves as a superconducting kinetic inductance element when the current induced therein is less than a threshold level and behaves as a normal, non-superconducting inductor when the current induced therein is greater than the threshold level.

### REFERENCE TO RELATED APPLICATIONS

This application claims priority to, and for the purposes of the United States the benefit under 35 USC 119 in connection with, U.S. application Ser. No. 63/105041 filed 23 Oct. 2020, which is hereby incorporated herein by reference.

### TECHNICAL FIELD

This disclosure relates to superconducting inductors. Particular embodiments provide circuits which permit tunable control of superconducting inductors.

### BACKGROUND

At a basic level, superconducting electronics are made of two circuit elements—capacitors and inductors. Combinations of these two circuit elements enable resonators to be built that can store electromagnetic energy and to build filters. These two circuit elements also have applications in quantum sensing, classical sensing (e.g. radio-astronomy) and superconducting technology.

The ability of superconducting circuits to process information, such as information processing involved in superconducting quantum computing, typically involves circuit non-linearity. The non-linearity of a circuit response for a superconducting circuit element enables the ability to “tune” (e.g. change) the inductance and/or capacitance of a superconducting circuit element dynamically using a voltage or current control signal. Such non-linearity, for example, is analogous to the non-linearity provided by conventional transistors in classical circuits, where a voltage can be used to control the channel conductivity.

Non-linearity of superconducting electronics enables a number of functionalities. For example, an inductance non-linearity enables the formation of quantum bits to encode quantum information in by introducing a non-linearity in an LC oscillator. Without this nonlinearity, a well-defined computational space is not available. The non-linearity of inductance also allows other functionality such as: reading out of information in the processor, via a tunable resonator; fabricating sensitive quantum-limited amplifiers; and fabricating responsive classical and/or quantum sensors. Tunable inductors also make some fabricated systems more robustly manufacturable because tunable inductors provide a strategy for coping with circuit imperfections. For example, if a tunable inductor is fabricated but the result is not exactly as planned due to manufacturing imperfections, a control signal may be used to tune the inductor to compensate for such manufacturing imperfections.

Two known inductance nonlinearities come from Josephson Junctions (JJs) and Kinetic Inductance (KI) devices. Conventional tunable inductors in superconducting electronics have the deficiency that they either have relatively limited tunability (i.e. the ability to change their inductance over a limited range) and relatively high current carrying capability, or they have relatively high tunability (i.e. the ability to change their inductance over a relatively high range) and low current-carrying capability. To be more quantitative, KI-based devices typically allow relatively large supercurrents (density ˜10⁶ A/cm²) to flow, but are limited to a rather small tunability of around ˜20%, where the percentage tunability is determined according to

$$\frac{( {L}_{ma x} - {L}_{min} )}{{L}_{min}} .$$

JJ-based devices, on me other hand, typically enable greater tunability (e.g. ˜500%), but they typically can only carry a limited current before ceasing to be superconducting. State of the art values for JJ based devices have critical current densities 10² to nearly 10³ A/cm² for Nb/Al-AlOx/Nb junctions and 10⁴ A/cm² for Nb/Al/AlN/Nb junctions.

There is a general desire to provide a superconducting circuit element that functions as a tunable inductor with the ability to provide both relatively high current carrying capacity and relatively high tunability.

The foregoing examples of the related art and limitations related thereto are intended to be illustrative and not exclusive. Other limitations of the related art will become apparent to those of skill in the art upon a reading of the specification and a study of the drawings.

### SUMMARY

The following embodiments and aspects thereof are described and illustrated in conjunction with systems, tools and methods which are meant to be exemplary and illustrative, not limiting in scope. In various embodiments, one or more of the above-described problems have been reduced or eliminated, while other embodiments are directed to other improvements.

One aspect of the invention provides a controllable superconducting inductor circuit comprising: a plurality of sub-circuits, each sub-circuit comprising: an inductor element; and a control element coupled to the inductor element to induce current in the inductor element in response to a control signal received at the control element. The inductor elements from the plurality of sub-circuits are arranged (e.g. electrically connected) in parallel between a first pair of nodes to provide a tunable total inductance Lₜᵤₙ. For each of the plurality of sub-circuits, the inductor element behaves as a superconducting kinetic inductance element when the current induced therein is less than a threshold level and behaves as a normal, metallic, non-superconducting inductor when the current induced therein is greater than the threshold level.

The control elements from the plurality of sub-circuits may be arranged (e.g. electrically connected) in parallel between a second pair of nodes.

Each of the control elements from each of the plurality of sub-circuits may be electrically connected to a corresponding control input node. The plurality of control elements from the plurality of sub-circuits may be electrically connected to a collective control output node.

Each of the control elements from each of the plurality of sub-circuits may be electrically connected to a corresponding control input node and a corresponding control output node.

The control signal may comprise a control current I_{c} that flows between the second pair of nodes.

For each of the plurality of sub-circuits, the control signal received at the control element may comprise a corresponding control current that flows between the corresponding control input node and the collective control output node.

For each of the plurality of sub-circuits, the control signal received at the control element may comprise a corresponding control current that flows between the corresponding control input node and the corresponding control output node.

A degree of coupling between the control element and the inductor element in a first one of the plurality of sub-circuits may be different than a degree of coupling between the control element and the inductor element in a second one of the plurality of sub-circuits.

A degree of coupling between the control element and the inductor element in each of the plurality of sub-circuits may be different.

A degree of coupling between the control element and the inductor element in each of the plurality of sub-circuits may be the same.

A geometry of the inductor element in a first one of the plurality of sub-circuits may be different than a geometry of the inductor element in a second one of the plurality of sub-circuits.

A geometry of the inductor element in each of the plurality of sub-circuits may be different.

A geometry of the inductor element in each of the plurality of sub-circuits may be the same.

The geometry of the inductor element in at least one of the plurality of sub-circuits may comprise a ladder-like geometry with a pair of elongated segments and a plurality of rung segments that extend transversely between the pair of elongated segments at locations spaced apart along a direction of elongation of the elongated segments.

The geometry of the inductor element in at least one of the plurality of sub-circuits may comprise a wire

The control element of each sub-circuit may comprise a superconducting coil.

A geometry of the superconducting coil in a first one of the plurality of sub-circuits may be different than a geometry of the superconducting coil in a second one of the plurality of sub-circuits.

A geometry of the superconducting coil in each of the plurality of sub-circuits may be different.

A spacing between the control element and the inductor element in a first one of the plurality of sub-circuits may be different than a spacing between the control element and the inductor element in a second one of the plurality of sub-circuits.

A spacing between the control element and the inductor element in each of the plurality of sub-circuits may be different.

A spacing between the control element and the inductor element in each of the plurality of sub-circuits may be the same.

A degree of coupling between the control element and the inductor element in a first one of the plurality of sub-circuits may be different than a degree of coupling between the control element and the inductor element in a second one of the plurality of sub-circuits.

A degree of coupling between the control element and the inductor element in a first one of the plurality of sub-circuits may be different than a degree of coupling between the control element and the inductor element in a second one of the plurality of sub-circuits.

A layer of soft magnetic material may be located atop and/or under at least one of the plurality of sub-circuits for increasing a degree of coupling between the control element and the inductor element in the at least one of the plurality of sub-circuits.

Another aspect of the invention provides a method for controlling a tunable total inductance Lₜᵤₙ between a pair of nodes. The method comprises: providing a plurality of sub-circuits, each sub-circuit comprising: an inductor element; and a control element coupled to the inductor element to induce current in the inductor element in response to a control signal received at the control element; wherein the inductor elements from the plurality of sub-circuits are arranged (e.g. electrically connected) in parallel between the pair of nodes to provide the total inductance Lₜᵤₙ; controlling the control signal received by at least one control element between: a first control signal level wherein the current induced in the corresponding inductor element is below a threshold level and the inductor element behaves as a superconducting kinetic inductance element; and a second control signal level wherein the current induced in the corresponding inductor element is above the threshold level and the inductor element behaves as a normal, non-superconducting inductor.

The control elements may be connected in parallel between a second pair of nodes and controlling the control signal received at the at least one control element may comprise controlling a circuit control current between the second pair of nodes.

Each of the control elements from each of the plurality of sub-circuits may be electrically connected to a corresponding control input node. The plurality of control elements from the plurality of sub-circuits may be electrically connected to a collective control output node. Controlling the control signal received at the at least one control element may comprise controlling a control current between the control input node corresponding to the at least one control element and the collective control output node.

Each of the control elements from each of the plurality of sub-circuits may be electrically connected to a corresponding control input node and a corresponding control output node. Controlling the control signal received at the at least one control element may comprise controlling a control current between the control input node and the control output node corresponding to the at least one control element.

In addition to the exemplary aspects and embodiments described above, further aspects and embodiments will become apparent by reference to the drawings and by study of the following detailed descriptions.

### BRIEF DESCRIPTION OF THE DRAWINGS

Exemplary embodiments are illustrated in referenced figures of the drawings. It is intended that the embodiments and figures disclosed herein are to be considered illustrative rather than restrictive.

FIG. 1 is a block diagram of a tunable superconducting inductor device according to a particular embodiment.

FIG. 2 is a schematic depiction of the FIG. 1 device in more detail according to a particular embodiment.

FIG. 3 schematically depicts one sub-circuit of the FIG. 2 device according to a particular example embodiment.

FIG. 4 is a schematic depiction of a tunable superconducting inductor device according to another particular embodiment.

FIG. 5 is a schematic depiction of a tunable superconducting inductor device according to another particular embodiment.

### DESCRIPTION

Throughout the following description specific details are set forth in order to provide a more thorough understanding to persons skilled in the art. However, well known elements may not have been shown or described in detail to avoid unnecessarily obscuring the disclosure. Accordingly, the description and drawings are to be regarded in an illustrative, rather than a restrictive, sense.

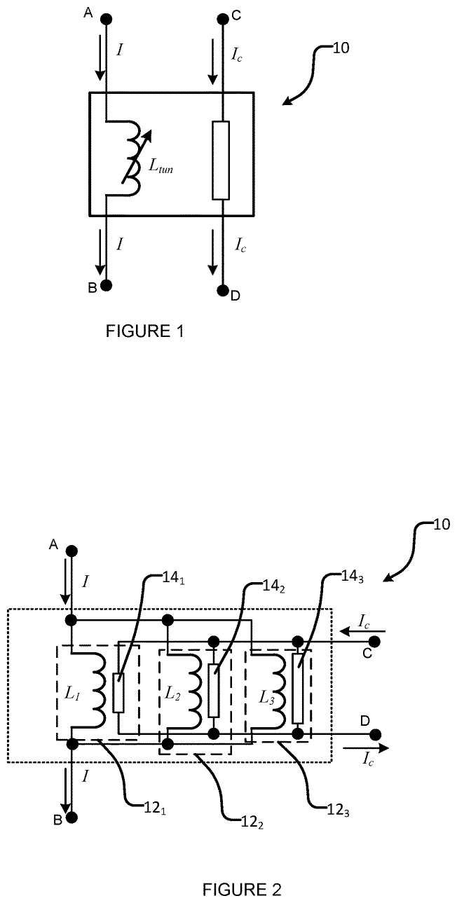

FIG. 1 is a block diagram of a tunable superconducting inductor device 10 according to a particular embodiment. Device 10 comprises a two-port network with four terminals A, B, C, D with port AB (defined between terminals A, B) providing a tunable inductance Lₜᵤₙ carrying a current I and port CD (defined between terminals C, D) providing a control signal I_{c}. The inductance Lₜᵤₙ of device 10 is tunable in the sense that the inductance L can be changed by varying the control current I_{c} between terminals C, D. In particular embodiments, the inductance Lₜᵤₙ can be increased by increasing the control current I_{c} between terminals C, D, thereby providing circuit non-linearity for device 10.

FIG. 2 shows inductor device 10 in more detail according to a particular embodiment. In particular, FIG. 2 shows that device 10 comprises a plurality of sub-circuits 12₁, 12₂, 12₃, . . . 12ₙ (collectively, sub-circuits 12) schematically illustrated using dashed boxes. In the illustrated schematic example device 10 shown in FIG. 2, there are three sub-circuits 12, but it will be appreciated that, in general, there may be any number n of sub-circuits 12. Each of sub-circuits 12 comprises: a tunable inductor transformer having a tunable inductor L₁, L₂, L₃ . . . Lₙ (collectively, inductors L); and corresponding control element 14₁, 14₂, 14₃, . . . 14ₙ (collectively, control elements 14).

In the schematic depiction of FIG. 2, control elements 14 are shown as rectangular boxes. The size of the rectangular boxes illustrated in FIG. 2 are meant to depict the degree of coupling (explained in more detail below) between control elements 14 and their corresponding inductors L. That is, the larger the illustrated size of the rectangular box corresponding to a particular control element 14, the correspondingly greater degree of coupling between that control element 14 and its corresponding inductor L. The degree of coupling between a control element 14 and its corresponding inductor L may be achieved by a variety of techniques, as explained in more detail below. Advantageously, in the illustrated embodiment, at least some of sub-circuits 12 have different degrees of coupling between their respective control elements 14 and inductors L. In some embodiments, each sub-circuit 12 of device 10 has a different degree of coupling (between its control element 14 and inductor L) from all of the other sub-circuits 12 in device 10. In the particular case of the exemplary FIG. 2 illustration, the degree of coupling increases in sub-circuits 12 from left to right.

Inductors L may also be referred to herein as target inductors L because they are the targets to be tuned. Target inductors L may comprise a highly disordered superconducting wire that inherits a relatively large kinetic inductance due to the disorder in the superconducting state. As explained in more detail below, the tunability of target inductors L arises in device 10 from a combination of two nonlinear mechanisms inherent to superconductors: the kinetic inductance nonlinearity and the dissipative non-linearity at the transition to the normal state.

In the FIG. 2 embodiment, when a control current I_{c} is applied between terminals C, D, this control current I_{c} is divided between parallel sub-circuits 12 and, in particular, between parallel control elements 14. Control elements 14 are coupled to their respective target inductances L and induce corresponding currents in each of their respective target inductances L. This coupling may be due to magnetic fields created by control elements 14 and can be quantified by the change in inductance of the target inductor L per unit current in control element 14. When target inductors L are operating in a superconducting state (e.g. when the control current I_{c} is not present or is sufficiently small), the effective inductance Lₜᵤₙ between terminals A, B is given by Lₜᵤₙ=(L₁⁻¹+L₂⁻¹+L₃⁻¹+L₄⁻¹+ . . . Lₙ⁻¹)⁻¹. This may represent a relatively small inductance value Lₜᵤₙ between terminals A, B. Where all of the target inductors L are designed to have inductances that are sufficiently different from one another, then the inductance value Lₜᵤₙ when all of the target inductor L are operating in a superconducting state can be considered to be approximately equal to the smallest inductance from among the target inductors L. For example, if L₁<<L₂<<L₃ . . . <<Lₙ, then, when all of the target inductors L are operating in a superconducting state, then the effective inductance Lₜᵤₙ between terminals A, B is approximately Lₜᵤₙ≈L₁.

If the control current I_{c} applied between terminals C, D is increased, there will be a scenario where the induced current i in a target inductor L reaches the critical current and the target inductance changes from a superconducting state to a normal (i.e. non-superconducting) state. Advantageously, because of the different degrees of coupling in each sub-circuit 12, different target inductors L will turn normal with different amounts of control current I_{c}. For example, in the illustrated example of FIG. 2, where sub-circuit 12₃ has the greatest degree of coupling, inductor L₃ may turn normal at a relatively low amount of control current I_{c}. When a target inductor L turns normal, it becomes somewhat resistive. If the resistance is sufficiently high, the current flow through that target inductor L will effectively be blocked, thereby effectively eliminating (or substantially reducing to near zero) that target inductor's contribution to the inductance Lₜᵤₙ between terminals A, B, thereby effectively increasing the inductance Lₜᵤₙ between terminals A, B. As each of the n target inductors turns normal, there will be corresponding discrete jumps in the Lₜᵤₙ between terminals A, B. If all but one of the target inductors turn normal (e.g. if L₁, L₂, . . . Lₙ₋₁ turn normal), then the effective inductance between terminals A and B is reduced to that of the one remaining superconducting inductor Lₗₐₛₜ.

Device 10 is estimated to be able to carry current densities on the order of 10⁶ A/cm²—see Hortensius et al. Critical-current reduction in thin superconducting wires due to current crowding. In Appl. Phys. Lett. 100, 182602 (2012).

The tuning ratio of device 10 may be given by

$$\frac{{L}_{last}}{{( \frac{1}{{L}_{1}} + \frac{1}{{L}_{2}} + . . . \frac{1}{{L}_{n}} )}^{- 1}} .$$

This tuning ratio is defined by the degree of coupling between target inductors L and control elements 14 in each sub-circuit 12 and is not limited to the tunability of the kinetic inductance of inductors L when they are in the superconducting state. The degree of coupling between target inductors L and control elements 14 in each sub-circuit 12 may be defined at least in part by the geometry of target inductors L and control elements 14. Such geometric parameters may include, without limitation: the geometry of target inductors L, the geometry of control elements 14 and the proximity of target inductors L to control elements 14.

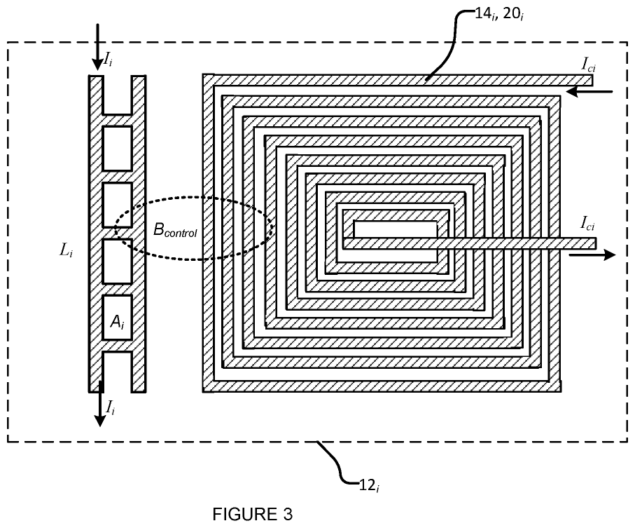

FIG. 3 schematically depicts one sub-circuit 12ᵢ of device 10 according to a particular example embodiment. Sub-circuit 12ᵢ comprises target inductor Lᵢ and control element 14ᵢ. Sub-circuit 12i can be fabricated on-chip using planar fabrication technologies including sputtering deposition of superconductors and dielectrics and reactive ion etching. Circuit devices may have approximate dimensions on the order of 1-100 microns, for example.

In the illustrated FIG. 3 embodiment, target inductor Lᵢ comprises a highly disordered superconducting wire having loops with area Aᵢ. Target inductor Lᵢ inherits a relatively large kinetic inductance due to the disorder in the superconducting material from which it is fabricated. Current Iᵢ is induced in target inductor Lᵢ via the magnetic field B_{control} that threads (e.g. generates magnetic flux that passes through) the loops with area Aᵢ. The current Iᵢ induced in target inductor Lᵢ changes the kinetic inductance via the kinetic inductance nonlinearity. The loops of target inductor Lᵢ form a structure having a ladder-like appearance. In some embodiments, it may be desirable for the thickness of the conducting portions of target inductor Lᵢ to be relatively thin. In some embodiments, the thickness of the conducting portions of target inductor Lᵢ is less than 100 nm. In some embodiments, this thickness is less than 50 nm. In some embodiments, this thickness is less than 20 nm. This relatively thin dimensionality ensures that the kinetic inductance associated with the energy stored in the motion of the Cooper pairs dominates the magnetic inductance associated with energy stored in the magnetic field due to current flow. The dominance of the energy stored in the motion of the Cooper pairs is desirable to enhance the inductance L₁, L₂, . . . Lₙ that can be obtained per unit length, effectively making device 10 smaller than if the magnetic inductance alone was employed.

Target inductor Lᵢ is not limited to the form factor shown in FIG. 3. In some embodiments, target inductor Lᵢ may comprise any form of superconducting element that has some form of inductance. For example, in some embodiments, target inductor Lᵢ may comprise a single superconducting wire. While such wire-based inductors may be less efficient (in terms of coupling) than the ladder-like structure shown in FIG. 3, wire-based inductors may offer the advantage of relatively simple and perhaps less expensive fabrication.

In some embodiments, target inductor Lᵢ may be fabricated from high kinetic inductance disordered (alloyed) superconductor materials, such as NbTiN, NbN, AlSi, AlMn, and/or WSi, for example. Having a relatively high kinetic inductance may enhance the tunability and decrease the size of device 10.

In the illustrated embodiment, control element 14ᵢ comprises a control coil 20ᵢ. Current flowing in control coil 20ᵢ induces the magnetic field B_{control} that tunes target inductor Lᵢ. Control coil 20ᵢ may be fabricated from a relatively high temperature superconductor to generate a relatively high magnetic field B_{control}.

As discussed above, a factor in the design of device 10 is the degree of coupling between control element 14 and target inductor L in each sub-circuit 12. As also discussed above, the degree of coupling between target inductors L and control elements 14 in each sub-circuit 12 may be defined at least in part by the geometry of target inductors L and control elements 14. This is true in the case of the FIG. 3 embodiment of sub-circuit 12₁, where such geometric parameters may include, without limitation: the geometry of target inductor Lᵢ, the geometry of control coil 20ᵢ and the proximity of control coil 20ᵢ to target inductor Lᵢ. Particular geometric factors that impact the degree of coupling in the case of the FIG. 3 embodiment of sub-circuit 12i include, without limitation, the number of turns in control coil 20ᵢ, the spacing between conducting portions of control coil 20ᵢ, the spacings and/or areas between “rungs” in the ladder shape of target inductors Lᵢ (e.g. the areas of the loops of target inductors Lᵢ), the spacing between target inductors Lᵢ and corresponding control coils 20ᵢ, and/or the like.

Factors that impact the degree of coupling are not limited to geometric parameters. Other aspects of the FIG. 3 embodiment of sub-circuit 12i that may impact the degree of coupling between control coil 20ᵢ and target inductor Lᵢ include, without limitation, selective deposition of magnetic materials. For example, in some embodiments, one or more soft magnetic materials (e.g. with relative magnetic permeability greater (preferably significantly greater) than unity) can be deposited adjacent to (e.g. atop and/or under) some or all of sub-circuits 12 in any given device. If such a material is metallic, such as for nickel-iron alloys, for example, the soft magnetic material may be electrically isolated from target inductor Lᵢ and control element 14 by a suitable layer of electrically insulating material. Such soft magnetic materials can increase the coupling between control element and target inductor Lᵢ.

Other geometric factors may have other impacts on the performance of control coils 20ᵢ and/or target inductors Lᵢ. For example, the thickness and/or width of the conducting portions of control coils 20ᵢ can impact the maximum current that can be applied to coils 20ᵢ before they turn to a normal state. As another example, the thickness and/or width of the conducting portions of target inductors Lᵢ may impact the degree of coupling (and/or the amount of induced current) at which the target inductors Lᵢ turn to a normal state.

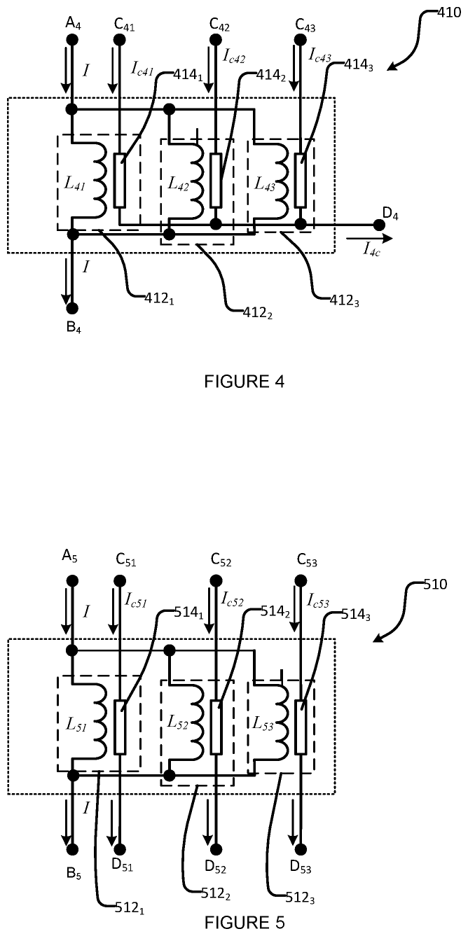

FIG. 4 is a schematic depiction of a tunable superconducting inductor device 410 according to another particular embodiment. Device 410 is similar in many respects to device 10 (FIGS. 1 and 2). Device 410 differs from device 10 in that device 410 comprises individually addressable and/or controllable control input nodes C₄₁, C₄₂, C₄₃ . . . C₄ₙ (collectively, control input nodes C₄) for the control elements 414₁, 414₂, 414₃ . . . 414ₙ (collectively, control elements 414) of each sub-circuit 412₁, 412₂, 412₃ . . . 412ₙ (collectively, sub-circuits 412) with a common control output node D₄. Inductors L₄₁, L₄₂, . . . L₄ₙ (collectively, inductors L₄) are connected between nodes A₄ and B₄ in the same manner as the inductors of device 10. Individual control input nodes C₄ of the device 410 can be driven with different control currents I_{c41}, I_{c42}, I_{c43} . . . I_{c4n} (collectively, control currents I_{c4}) based on signals from a suitably configured digital controller (e.g. one or more processors) or other control circuit (not shown) to individually control the control currents I_{c4} provided to control elements 314 and to thereby control which of inductors L₄ are superconducting and which of inductors L₄ are turned normal (non-superconducting), thereby permitting tunability of circuit 410 (the inductance Iₜᵤₙ between nodes A4 and B4).

Because of the individually addressable control elements 414 in device 410, the degree of coupling between different control elements 414 and their respective inductors L₄ can be the same, as shown in FIG. 4 by the boxes representing the control elements 414 being the same size. This is not necessary, some or all of the control elements 414 may have different degrees of coupling with their inductors L₄. In other respects, control elements 414 and inductors L₄ may be similar in their construction and function to control elements 14 and inductors analogous in their function to elements 12 and 14 in device 10.

Some or all of the target inductors L₄ may have inductances that are the same, similar to or significantly different to each other (significantly different as defined for inductors L in device 10). A suitable digital controller and/or control circuit can alter the inductance values between terminals A₄ and B₄ by altering how much control current I_{c4} is provided to each control input node C₄₁, C₄₂, . . . C₄ₙ to control which inductors L₄ are superconducting and non-superconducting.

FIG. 5 is a schematic depiction of a tunable superconducting inductor device 510 according to another particular embodiment. Device 510 is similar in many respects to device 410 (FIG. 4) and comprises individually addressable and/or controllable control input nodes C₅₁, C₅₂, C₅₃ . . . C₅ₙ (collectively, control input nodes C₅) for the control elements 514₁, 514₂, 514₃ . . . 514ₙ (collectively, control elements 514) of each sub-circuit 512₁, 512₂, 512₃ . . . 512ₙ (collectively, sub-circuits 512). Inductors L₅₁, L₅₂, . . . L₅ₙ (collectively, inductors L₅) are connected between nodes A₅ and B₅ in the same manner as the inductors of device 10. Device 510 of the FIG. 5 embodiment differs from device 410 of the FIG. 4 embodiment in that control output nodes D₅₁, D₅₂ . . . D₅ₙ (collectively control output nodes D₅) are separate from one another, meaning that the currents I_{c51}, I_{c52}, . . . I_{c5n} (collectively, control currents I_{c5}) provided to any of control elements 514 can be controlled or otherwise provided by separate circuits and/or separate digital controllers (although such separation is not necessary).

In some embodiments, control elements 514 of the FIG. 5 embodiment may be configured to operate differently from one another (e.g. with different electrical operating parameters), although this is not necessary. In other respects, inductor device 510 may be similar to inductor device 410 described above.

While a number of exemplary aspects and embodiments have been discussed above, those of skill in the art will recognize certain modifications, permutations, additions and sub-combinations thereof. It is therefore intended that the following appended claims and claims hereafter introduced are interpreted to include all such modifications, permutations, additions and sub-combinations as are consistent with the broadest interpretation of the specification as a whole.

1. A controllable superconducting inductor circuit comprising:
a plurality of sub-circuits, each sub-circuit comprising: an inductor element; and a control element coupled to the inductor element to induce current in the inductor element in response to a control signal received at the control element; and
wherein the inductor elements from the plurality of sub-circuits are arranged in parallel between a first pair of nodes to provide a tunable total inductance Lₜᵤₙ;
wherein for each of the plurality of sub-circuits, the inductor element behaves as a superconducting kinetic inductance element when the current induced therein is less than a threshold level and behaves as a normal, metallic, non-superconducting inductor when the current induced therein is greater than the threshold level.

2. The circuit of claim 1 wherein the control elements from the plurality of sub-circuits are arranged in parallel between a second pair of nodes.

3. The circuit of claim 1 where each of the control elements from each of the plurality of sub-circuits is electrically connected to a corresponding control input node and wherein the plurality of control elements from the plurality of sub-circuits are electrically connected to a collective control output node.

4. The circuit of claim 1 where each of the control elements from each of the plurality of sub-circuits is electrically connected to a corresponding control input node and a corresponding control output node.

5. The circuit of claim 2 wherein the control signal comprises a control current I_{c} that flows between the second pair of nodes.

6. The circuit of claim 3 wherein, for each of the plurality of sub-circuits, the control signal received at the control element comprises a corresponding control current that flows between the corresponding control input node and the collective control output node.

7. The circuit of claim 4 wherein, for each of the plurality of sub-circuits, the control signal received at the control element comprises a corresponding control current that flows between the corresponding control input node and the corresponding control output node.

8. The circuit of claim 1 wherein a degree of coupling between the control element and the inductor element in a first one of the plurality of sub-circuits is different than a degree of coupling between the control element and the inductor element in a second one of the plurality of sub-circuits.

9. The circuit of claim 1 wherein a degree of coupling between the control element and the inductor element in each of the plurality of sub-circuits is different.

10. The circuit of claim 1 wherein a geometry of the inductor element in a first one of the plurality of sub-circuits is different than a geometry of the inductor element in a second one of the plurality of sub-circuits.

11. The circuit of claim 1 wherein a geometry of the inductor element in each of the plurality of sub-circuits is different.

12. The circuit of claim 1 wherein the geometry of the inductor element in at least one of the plurality of sub-circuits comprises a ladder-like geometry with a pair of elongated segments and a plurality of rung segments that extend transversely between the pair of elongated segments at locations spaced apart along a direction of elongation of the elongated segments.

13. The circuit of claim 1 wherein the geometry of the inductor element in at least one of the plurality of sub-circuits comprises a wire.

14. The circuit of claim 1 wherein the control element of each sub-circuit comprises a superconducting coil.

15. The circuit of claim 14 wherein a geometry of the superconducting coil in a first one of the plurality of sub-circuits is different than a geometry of the superconducting coil in a second one of the plurality of sub-circuits.

16. The circuit of claim 12 wherein a geometry of the superconducting coil in each of the plurality of sub-circuits is different.

17. The circuit of claim 1 wherein a spacing between the control element and the inductor element in a first one of the plurality of sub-circuits is different than a spacing between the control element and the inductor element in a second one of the plurality of sub-circuits.

18. The circuit of claim 1 wherein a spacing between the control element and the inductor element in each of the plurality of sub-circuits is different.

19. The circuit of claim 3 wherein a degree of coupling between the control element and the inductor element in a first one of the plurality of sub-circuits is different than a degree of coupling between the control element and the inductor element in a second one of the plurality of sub-circuits.

20. The circuit of claim 4 wherein a degree of coupling between the control element and the inductor element in a first one of the plurality of sub-circuits is different than a degree of coupling between the control element and the inductor element in a second one of the plurality of sub-circuits.

21. The circuit of claim 1 wherein a layer of soft magnetic material is located atop and/or under at least one of the plurality of sub-circuits for increasing a degree of coupling between the control element and the inductor element in the at least one of the plurality of sub-circuits.

22. A method for controlling a tunable total inductance Lₜᵤₙ between a pair of nodes, the method comprising:
providing a plurality of sub-circuits, each sub-circuit comprising: an inductor element; and a control element coupled to the inductor element to induce current in the inductor element in response to a control signal received at the control element;
wherein the inductor elements from the plurality of sub-circuits are arranged in parallel between the pair of nodes to provide the total inductance Lₜᵤₙ;
controlling the control signal received by at least one control element between:
a first control signal level wherein the current induced in the corresponding inductor element is below a threshold level and the inductor element behaves as a superconducting kinetic inductance element; and
a second control signal level wherein the current induced in the corresponding inductor element is above the threshold level and the inductor element behaves as a normal, non-superconducting inductor.

23. A method according to claim 22 wherein the control elements are connected in parallel between a second pair of nodes and wherein controlling the control signal received at the at least one control element comprises controlling a circuit control current between the second pair of nodes.

24. A method according to claim 22 wherein:
each of the control elements from each of the plurality of sub-circuits is electrically connected to a corresponding control input node;
the plurality of control elements from the plurality of sub-circuits are electrically connected to a collective control output node; and
controlling the control signal received at the at least one control element comprises controlling a control current between the control input node corresponding to the at least one control element and the collective control output node.

25. A method according to claim 22 wherein:
each of the control elements from each of the plurality of sub-circuits is electrically connected to a corresponding control input node and a corresponding control output node; and
controlling the control signal received at the at least one control element comprises controlling a control current between the control input node and the control output node corresponding to the at least one control element.
